(19) United States
(12) Patent Application Publication
(10) Pub. No.: US 2019/0295979 A1
(43) Pub. Date: Sep. 26, 2019

(54) SOLDER BUMP, FLIP CHIP STRUCTURE AND METHOD FOR PREPARING THE SAME

(71) Applicant: NANYA TECHNOLOGY CORPORATION, NEW TAIPEI CITY (TW)

(72) Inventor: CHIEN-CHUNG WANG, NEW TAIPEI CITY (TW)

(21) Appl. No.: 15/934,486

(22) Filed: Mar. 23, 2018

(51) Int. Cl. H01L 23/00; H01L 23/498; H01L 23/532; H01L 25/00

(52) U.S. Cl. CPC H01L 24/14; H01L 23/49816; H01L 2225/06513; H01L 25/50; H01L 23/53228

(57) ABSTRACT

The present disclosure provides a flip chip structure comprising a substrate, a bond pad, a passivation layer surrounding the bond pad, a first solder bump and a second solder bump. The first solder bump includes a first pillar formed on the bond pad and an adjacent portion of the passivation layer and extending in a vertical direction, a first coated layer fittingly formed on the first pillar, and a first solder ball formed on the first coated layer. The second solder bump includes a second pillar formed on a portion of the passivation layer and extending in the vertical direction, a second coated layer fittingly formed on the second pillar, and a second solder ball formed on the second coated layer. The first pillar includes a depression formed in the shape of an inverted cone and formed in a top surface of the first pillar.

### TECHNICAL FIELD

The present disclosure relates to a solder bump, a flip chip structure, and a method for preparing the same, and more particularly, to a solder bump including a pillar including a depression formed in the shape of an inverted cone and formed in a top surface of the pillar, a flip chip structure including the solder bump, and a method for preparing the flip chip structure.

### DISCUSSION OF THE BACKGROUND

A conventional flip chip structure includes a substrate, a bond pad formed on the substrate, a passivation layer formed on the substrate and surrounding the bond pad, an active bump formed on the bond pad and an adjacent portion of the passivation layer, and a dummy bump formed on the passivation layer and spaced apart from the active bump.

Because the dummy bump and the active bump are formed simultaneously, a height difference between the active bump and the dummy bump may lead to a necking phenomenon, a non-contact phenomenon or an overflow phenomenon after a conventional flip chip process and may reduce the effectiveness of the conventional flip chip process. As a result, there is a need for the height difference between the active bump and the dummy bump to be reduced.

This Discussion of the Background section is for background information only. The statements in this Discussion of the Background are not an admission that the subject matter disclosed in this section constitutes a prior art to the present disclosure, and no part of this section may be used as an admission that any part of this application, including this Discussion of the Background section, constitutes prior art to the present disclosure.

### SUMMARY

One aspect of the present disclosure provides a solder bump that has an innovative structure. The solder bump comprises a pillar, a coated layer fittingly formed on the pillar, and a solder ball formed on the coated layer. In some embodiments, the pillar includes a depression formed in the shape of an inverted cone and formed in a top surface of the pillar.

In some embodiments, the solder ball includes a bottom portion formed in the shape of an inverted cone. In some embodiments, a ratio of a height of the solder ball to a diameter of the pillar is between 0.6 and 0.8.

In some embodiments, the coated layer is formed in the shape of an inverted cone. In some embodiments, a top surface of the coated layer is rougher than a bottom surface of the coated layer.

Another aspect of the present disclosure provides a flip chip structure that can improve the effectiveness of a flip chip process. The flip chip structure comprises a substrate; a bond pad formed on the substrate, a passivation layer formed on the substrate and surrounding the bond pad; a first solder bump formed on the bond pad and an adjacent portion of the passivation layer; and a second solder bump formed on a portion of the passivation layer and spaced apart from the first solder bump. In some embodiments, the first solder bump includes a first pillar formed on the bond pad and the adjacent portion of the passivation layer and extending in a vertical direction, a first coated layer fittingly formed on the first pillar, and a first solder ball formed on the first coated layer. In some embodiments, the second solder bump includes a second pillar formed on the portion of the passivation layer and extending in the vertical direction, a second coated layer fittingly formed on the second pillar, and a second solder ball formed on the second coated layer. In some embodiments, the first pillar includes a depression formed in the shape of an inverted cone and formed in a top surface of the first pillar.

In some embodiments, a diameter of the first pillar of the first solder bump is different from a diameter of the second pillar of the second solder bump.

In some embodiments, the first solder ball includes a bottom portion formed in the shape of an inverted cone. In some embodiments, a ratio of a height of the first solder ball to the diameter of the first pillar is between 0.6 and 0.8.

In some embodiments, the first coated layer is formed in the shape of an inverted cone. In some embodiments, a top surface of the first coated layer is rougher than a bottom surface of the first coated layer.

In some embodiments, the first pillar of the first solder bump is made of copper.

In some embodiments, the first coated layer of the first solder bump is made of nickel.

In some embodiments, the first solder ball of the first solder bump is made of tin-silver.

Still another aspect of the present disclosure provides a method for forming a flip chip structure. The method includes the following steps. A substrate is provided. A bond pad is formed on the substrate. A passivation layer is formed on the substrate and surrounds the bond pad. A seed layer is sputtered on the bond pad and the passivation layer. A first solder bump and a second solder bump are simultaneously and respectively formed on a part of the seed layer that corresponds in position to the bond pad and an adjacent portion of the passivation layer and on another part of the seed layer that corresponds in position to a portion of the passivation layer. In some embodiments, the second solder bump is spaced apart from the first solder bump. In some embodiments, the first solder bump includes a first pillar formed on the part of the seed layer and extending in a vertical direction, a first coated layer fittingly formed on the first pillar, and a first solder ball formed on the first coated layer. In some embodiments, the second solder bump includes a second pillar formed on another part of the seed layer and extending in the vertical direction, a second coated layer fittingly formed on the second pillar, and a second solder ball formed on the second coated layer. In some embodiments, the first pillar includes a depression formed in the shape of an inverted cone and formed in a top surface of the first pillar.

In some embodiments, the step of simultaneously forming the first and second solder bumps comprises the following stages. A photoresist layer is coated on the seed layer. A lithography treatment is applied to the photoresist layer. The first and the second pillars are respectively and simultaneously electroplated on the part of the seed layer and another part of the seed layer. The first and second coated layers are respectively and simultaneously electroplated on the first and second pillars. Surface treatments are respectively and simultaneously applied to the first and second coated layers. The first and second solder balls are respectively and simultaneously electroplated on the first and second coated layers. The photoresist layer is stripped from the seed layer. A UBM etching treatment is applied for stripping the remaining part of the seed layer. The first and second solder balls are reflowed.

In some embodiments, a diameter of the first pillar is different from a diameter of the second pillar.

In some embodiments, the first solder ball includes a bottom portion formed in the shape of an inverted cone. In some embodiments, a ratio of a height of the first solder ball to the diameter of the first pillar is between 0.6 and 0.8.

In some embodiments, the first coated layer is formed in the shape of an inverted cone. In some embodiments, a top surface of the first coated layer is rougher than a bottom surface of the first coated layer.

In some embodiments, the first pillar of the first solder bump is made of copper.

In some embodiments, the first coated layer of the first solder bump is made of nickel.

In some embodiments, the first solder ball of the first solder bump is made of tin-silver.

In some embodiments, the second solder ball includes a bottom portion formed in the shape of an inverted cone. In some embodiments, a ratio of a height of the second solder ball to the diameter of the second pillar is between 0.6 and 0.8.

In some embodiments, the second coated layer is formed in the shape of an inverted cone. In some embodiments, a top surface of the second coated layer is rougher than a bottom surface of the second coated layer.

With the above-mentioned configurations of the flip chip structure, a height difference between the first solder bump and the second solder bump is reduced and the effectiveness of a flip chip process is thereby improved. Consequently, the drawbacks of a conventional flip chip structure can be alleviated.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be connected to the figures' reference numbers, which refer to similar elements throughout the description, and:

FIG. 1 is a perspective view of a flip chip structure in accordance with some embodiments of the present disclosure.

FIG. 2 is a side schematic view of the flip chip structure in accordance with some embodiments of the present disclosure.

FIG. 3A is a sectional view taken along line A-A in FIG. 1.

FIG. 3B is a sectional view taken along line B-B in FIG. 1.

FIG. 4 is a flow diagram illustrating a method for preparing the flip chip structure in accordance with some embodiments of the present disclosure.

FIGS. 5A, 5B, 5C, 5D, 5E 5F, 5G, 5H, 5I and 5J are schematic diagrams illustrating various stages of the method for preparing the flip chip structure in accordance with some embodiments of the present disclosure.

FIG. 6 is a schematic view illustrating a top surface of a first coated layer of a first solder bump of the flip chip structure in accordance with some embodiments of the present disclosure.

FIG. 7A is a schematic view illustrating a necking phenomenon of a comparative flip chip process.

FIG. 7B is a schematic view illustrating a non-contact phenomenon of the comparative flip chip process.

FIG. 7C is a schematic view illustrating an overflow phenomenon of the comparative flip chip process.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

As used herein, the terms “patterning” and “patterned” are used in the present disclosure to describe an operation of forming a predetermined pattern on a surface. The patterning operation includes various steps and processes and varies in accordance with different embodiments. In some embodiments, a patterning process is adopted to pattern an existing film or layer. The patterning process includes forming a mask on the existing film or layer and removing the unmasked film or layer with an etch or other removal process. The mask can be a photoresist, or a hard mask. In some embodiments, a patterning process is adopted to form a patterned layer directly on a surface. The patterning process includes forming a photosensitive film on the surface, conducting a photolithography process, and performing a developing process. The remaining photosensitive film is retained and integrated into the semiconductor device.

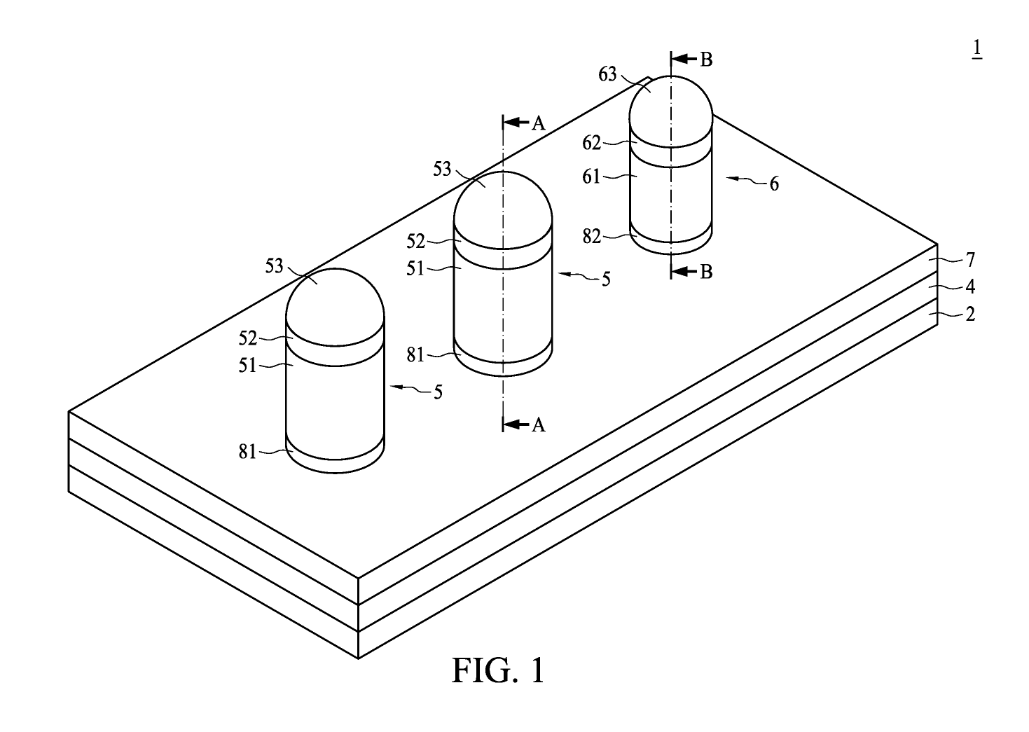

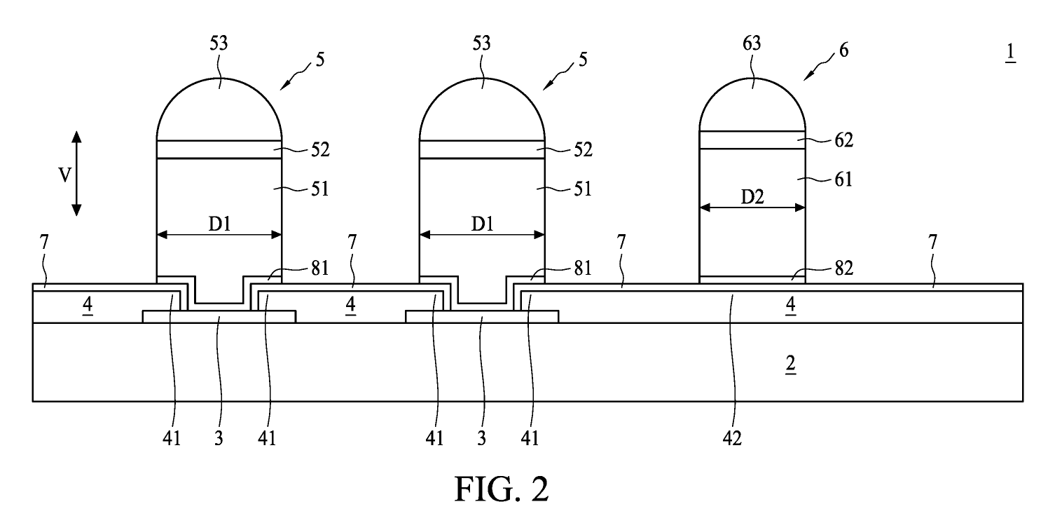

FIG. 1 is a perspective view of a flip chip structure 1 in accordance with some embodiments of the present disclosure, and FIG. 2 is a side schematic view of the flip chip structure 1 in accordance with some embodiments of the present disclosure. Referring to FIG. 1 and FIG. 2, the flip chip structure 1 comprises a substrate 2, a bond pad 3, a passivation layer 4, a first solder bump 5 and a second solder bump 6. In some embodiments, the bond pad 3 is formed on the substrate 1. In some embodiments, the passivation layer 4 is formed on the substrate 1 and surrounds the bond pad 3. In some embodiments, the first solder bump 5 is formed on the bond pad 3 and an adjacent portion 41 of the passivation layer 4. In some embodiments, the second solder bump 6 is formed on a portion 42 of the passivation layer 4 and is spaced apart from the first solder bump 5.

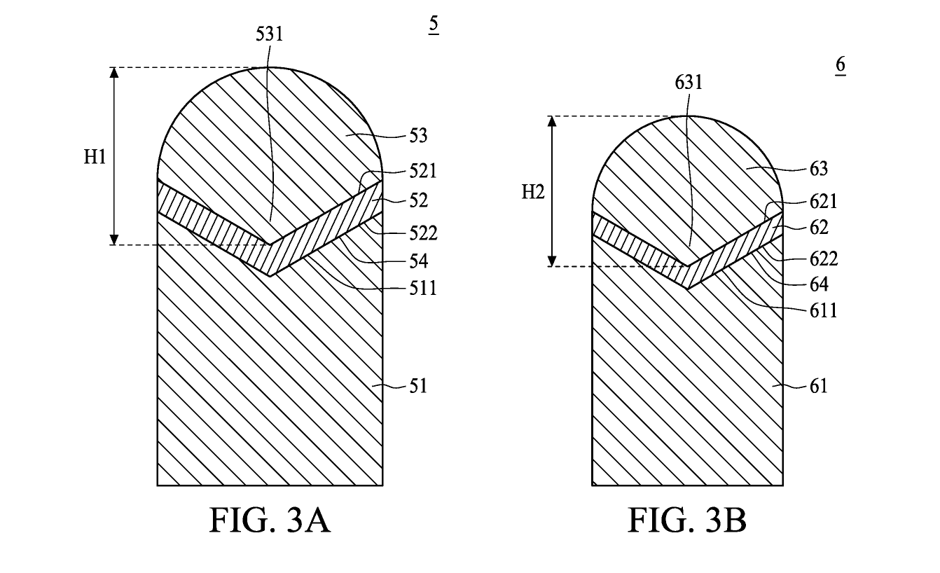

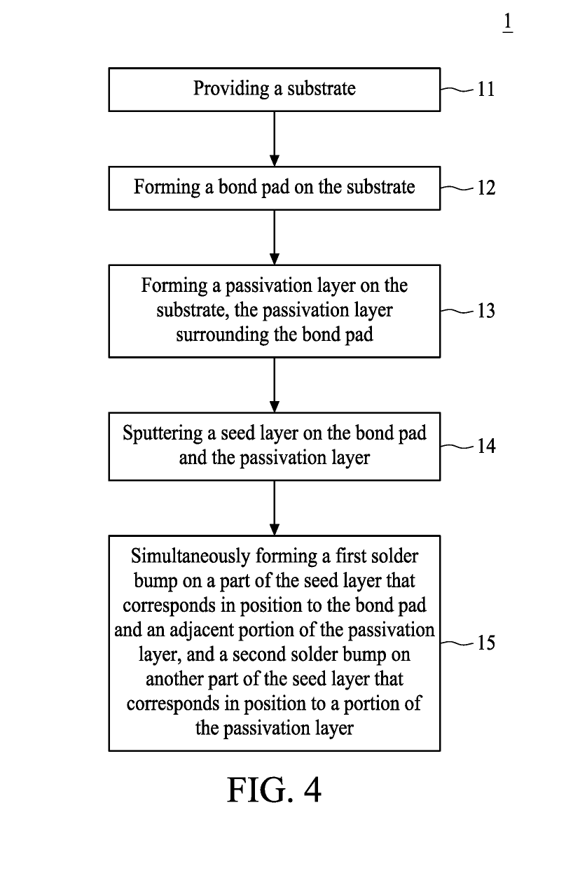

FIG. 3A is a sectional view taken along line A-A in FIG. 1. Referring to FIG. 1, FIG. 2 and FIG. 3A, the first solder bump 5 includes a first pillar 51, a first coated layer 52 and a first solder ball 53. In some embodiments, the first pillar 51 is formed on the bond pad 3 and the adjacent portion 41 of the passivation layer 4, extends in a vertical direction (V), and includes a depression 54 formed in the shape of an inverted cone and formed in a top surface 511 of the first pillar 51. In some embodiments, the first coated layer 52 is fittingly formed on the first pillar 51, is formed in the shape of an inverted cone, and includes a top surface 521 rougher than a bottom surface 522 of the first coated layer 52. In some embodiments, the first solder ball 53 is formed on the first coated layer 52 and includes a bottom portion 531 formed in the shape of an inverted cone. In some embodiments, a ratio of a height (H1) of the first solder ball 53 to a diameter (D1) of the first pillar 51 is between 0.6 and 0.8.

FIG. 3B is a sectional view taken along line B-B in FIG. 1. Referring to FIG. 1, FIG. 2 and FIG. 3B, the second solder bump 6 includes a second pillar 61, a second coated layer 62 and a second solder ball 63. In some embodiments, the second pillar 61 is formed on the portion 42 of the passivation layer 4, extends in the vertical direction, and includes a depression 64 formed in the shape of an inverted cone and formed in a top surface 611 of the second pillar 61. In some embodiments, the second coated layer 62 is fittingly formed on the second pillar 61, is formed in the shape of an inverted cone, and includes a top surface 621 rougher than a bottom surface 622 of the second coated layer 62. In some embodiments, the second solder ball 63 is formed on the second coated layer 62 and includes a bottom portion 631 formed in the shape of an inverted cone. In some embodiments, a ratio of a height (H2) of the second solder ball 63 to a diameter (D2) of the second pillar 61 is between 0.6 and 0.8. In some embodiments, the diameter of the first pillar 51 of the first solder bump 5 is different from the diameter of the second pillar 61 of the second solder bump 6.

In an exemplary embodiment, the flip chip structure 1 includes two bond pads 3, two first solder bumps 5 and one second solder bump 6. In other embodiments, the quantities of the bond pad 3, the first solder bump 5 and the second solder bump 6 may be varied.

In the exemplary embodiment, the substrate 2 is a printed circuit board (PCB), while, in other embodiments, the material of the substrate 2 may be varied.

In the exemplary embodiment, the bond pads 3 are made of aluminum, while, in other embodiments, the material of the bond pad 3 may be varied.

In the exemplary embodiment, the first pillars 51 of the first solder bumps 5 and the second pillar 61 of the second solder bump 6 are made of copper, while, in other embodiments, the materials of the first pillar 51 and the second pillar 61 may be varied.

In the exemplary embodiment, the first coated layers 52 of the first solder bumps 5 and the second coated layer 62 of the second solder bump 6 are made of nickel, while, in other embodiments, the materials of the first coated layer 52 and the second coated layer 62 may be varied.

In the exemplary embodiment, the first solder balls 53 of the first solder bumps 5 and the second solder ball 63 of the second solder bump 6 are made of tin-silver, while, in other embodiments, the materials of the first solder ball 53 and the second solder ball 63 may be varied.

In the exemplary embodiment, the first solder bumps 5 are active bumps which are electrically connected to the bond pads 3, and the second solder bump 6 is a dummy bump which is not electrically connected to the bond pad 3.

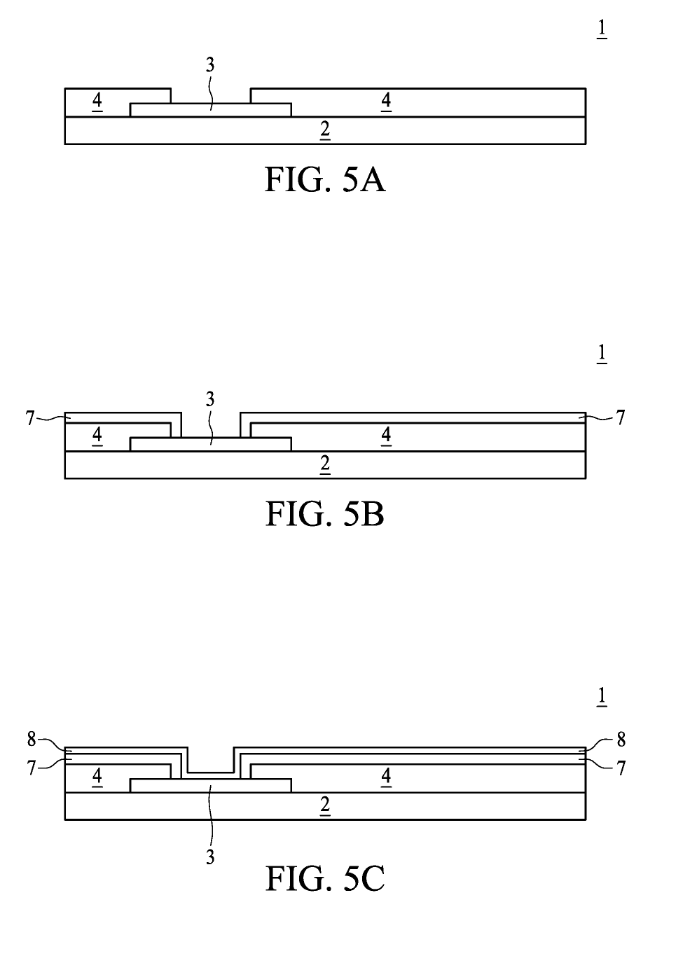

FIG. 4 is a flow diagram illustrating a method for preparing the flip chip structure 1 in accordance with some embodiments of the present disclosure. Referring to FIG. 1, FIG. 2 and FIG. 4, in some embodiments, the method for preparing the flip chip structure 1 includes a step 11: The substrate 2 is provided; a step 12: The bond pad 3 is formed on the substrate 2; a step 13: The passivation layer 4 is formed on the substrate 2, wherein the passivation layer 4 surrounds the bond pad 3; a step 14: A seed layer 8 is sputtered on the bond pad 3 and the passivation layer 4; and a step 15: The first solder bump 5 and the second solder bump 6 are simultaneously and respectively formed on a part 81 of the seed layer 8 that corresponds in position to the bond pad 3 and the adjacent portion 41 of the passivation layer 4 and on another part 82 of the seed layer 8 that corresponds in position to the portion 42 of the passivation layer 4.

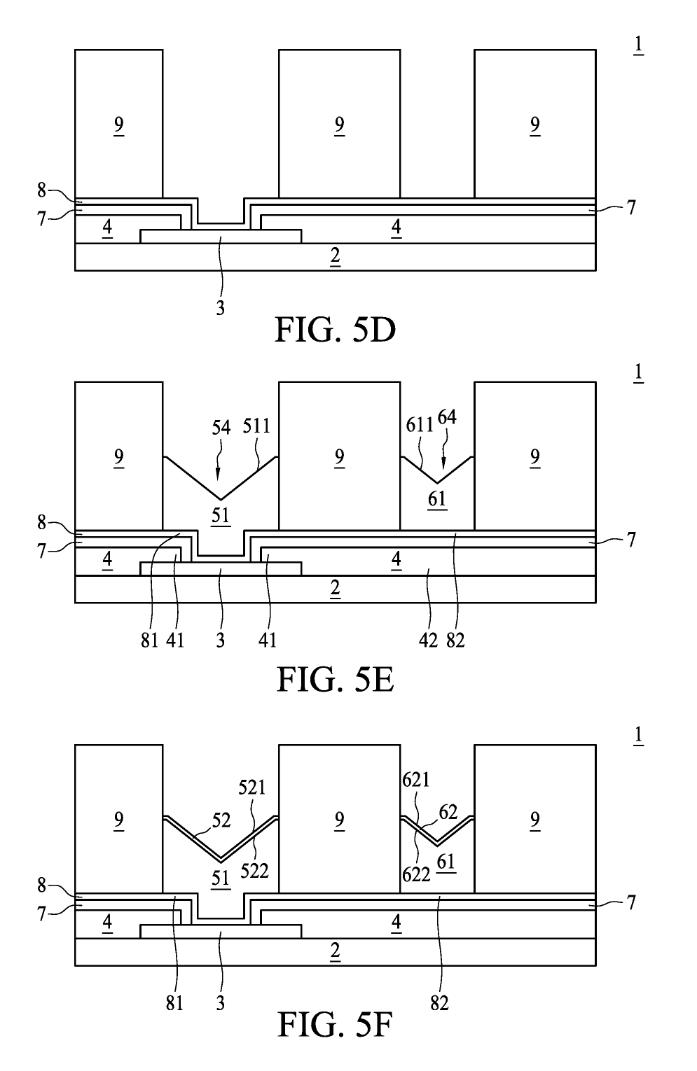

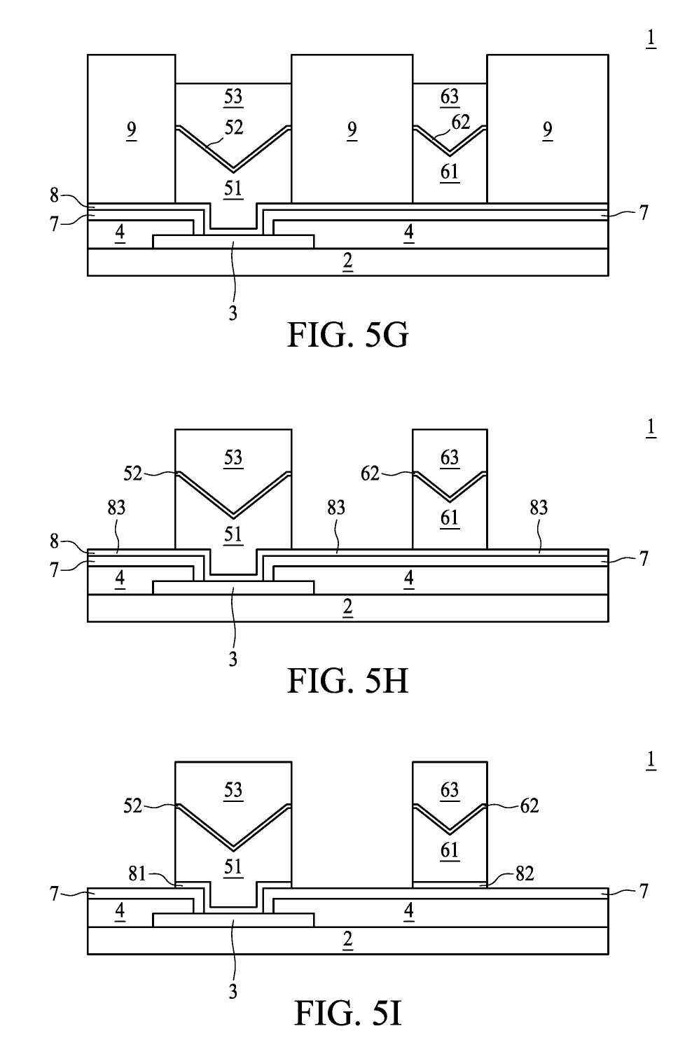

FIGS. 5A, 5B, 5C, 5D, 5E, 5F, 5G 5H, 5I and 5J are schematic diagrams illustrating various stages of the method for preparing the flip chip structure 1 in accordance with some embodiments of the present disclosure, and FIG. 6 is a schematic view illustrating the top surface 521 of the first coated layer 52 of the first solder bump 5 of the flip chip structure 1 in accordance with some embodiments of the present disclosure. First, referring to FIG. 5A, in some embodiments, the substrate 2 is provided according to the step 11; the bond pad 3 is formed on the substrate 2 according to the step 12; and the passivation layer 4 is formed on the substrate 2 and surrounds the bond pad 3 according to the step 13.

Referring to FIG. 5B, in some embodiments, a polyimide layer 7 is then coated on the passivation layer 4 for planarization purpose, while, in some other embodiments, the polyimide layer 7 may be omitted.

Referring to FIG. 5C, in some embodiments, the seed layer 8 is next sputtered on the bond pad 3 and passivation layer 4 according to the step 14. The seed layer 8 is sputtered on the bond pad 3 and the polyimide layer 7 for increasing the adhesion and the electrical conductivity of the first solder bump 5 and the second solder bump 6.

Subsequently, referring to FIGS. 5D, 5E, 5F, 5G, 5H, 5I and 5J, the first solder bump 5 and the second solder bump 6 are simultaneously formed on the seed layer 8 according to the step 15. In some embodiments, the first solder bump 5 is formed on the part 81 of the seed layer 8 that corresponds in position to the bond pad 3 and the adjacent portion 41 of the passivation layer 4, and the second solder bump 6 is formed on another part 82 of the seed layer 8 that corresponds in position to the portion 42 of the passivation layer 4.

During a process to form the first solder bump 5 and the second solder bump 6, referring to FIG. 5D, in some embodiments, a photoresist layer 9 is first coated on the seed layer 8 and a lithography treatment is then applied to the photoresist layer 9.

Referring to FIG. 5E, in some embodiments, the first pillar 51 of the first solder bump 5 is next electroplated on the part 81 of the seed layer 8 that corresponds in position to the bond pad 3 and the adjacent portion 41 of the passivation layer 4, while the second pillar 61 of the second solder bump 6 is simultaneously electroplated on another part 82 of the seed layer 8 that corresponds in position to the portion 42 of the passivation layer 4.

Referring, to FIG. 5F and FIG. 6, subsequently, in some embodiments, the first coated layer 52 of the first solder bump 5 and the second coated layer 62 of the second solder bump 6 are simultaneously and respectively electroplated on the first pillar 51 and the second pillar 61. After the first coated layer 52 and the second coated layer 62 are simultaneously and respectively electroplated on the first pillar 51 and the second pillar 62, surface treatments are respectively and simultaneously applied to the top surface 521 of the first coated layer 52 and the top surface 621 of the second coated layer 62 for respectively increasing the roughness of the top surface 521 of the first coated layer 52 and the roughness of the top surface 621 of the second coated layer 62.

Referring to FIG. 5G, in some embodiments, the first solder ball 53 of the first solder bump 5 and the second solder ball 63 of the second solder bump 6 are next respectively and simultaneously electroplated on the first coated layer 52 and the second coated layer 62.

Referring to FIG. 5G and FIG. 5H, in some embodiments, the photoresist layer 9 is subsequently stripped from the seed layer 8.

Referring to FIG. 5H and FIG. 5I, in some embodiments, a UBM etching treatment is then applied to the flip chip structure 1 for stripping the remaining part 83 of the seed layer 8 from the flip chip structure 1.

Referring to FIG. 5J, lastly, in some embodiments, each of the first solder ball 53 and the second solder ball 63 is reflowed to form a ball shape.

In the exemplary embodiment, the depressions 54, 64 of the first pillars 51 and the second pillar 61 are formed by changing the current density, while, in other embodiments, the depressions 54, 64 of the first pillar 51 and the second pillar 61 may be formed using other methods.

In the exemplary embodiment, the surface treatments using chemical solution to corrode the first coated layers 52 and the second coated layer 62 or using a steel ball to strike the first coated layers 52 and the second coated layer 62 so as to increase the roughness of the first coated layers 52 and the second coated layer 62. In other embodiments, the surface treatments may use other methods to increase the roughness of the coated layer 52 and the second coated layer 62.

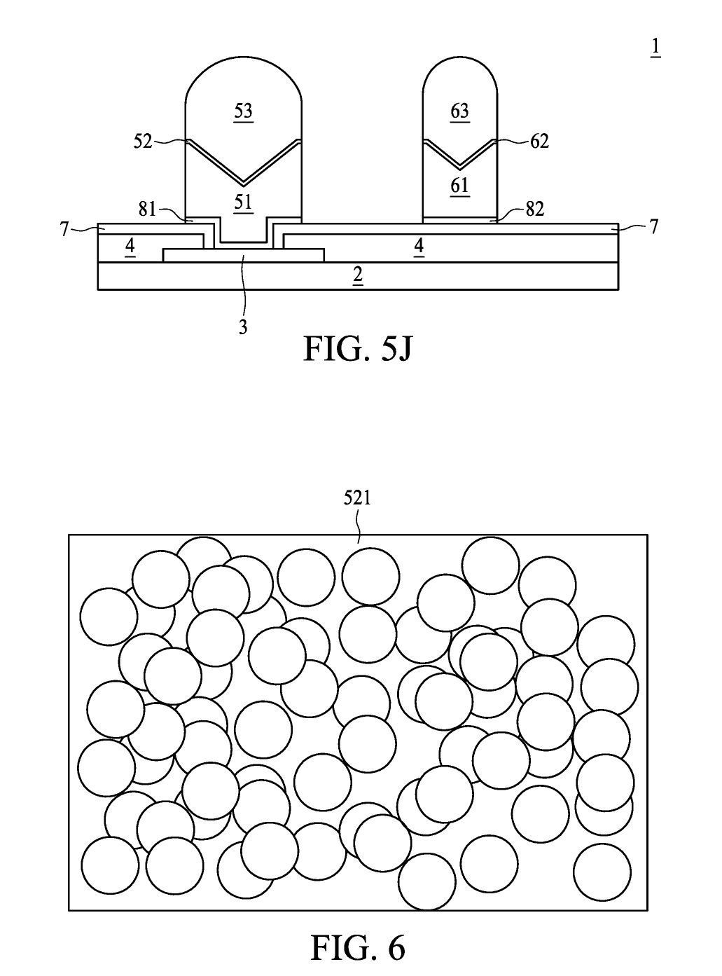

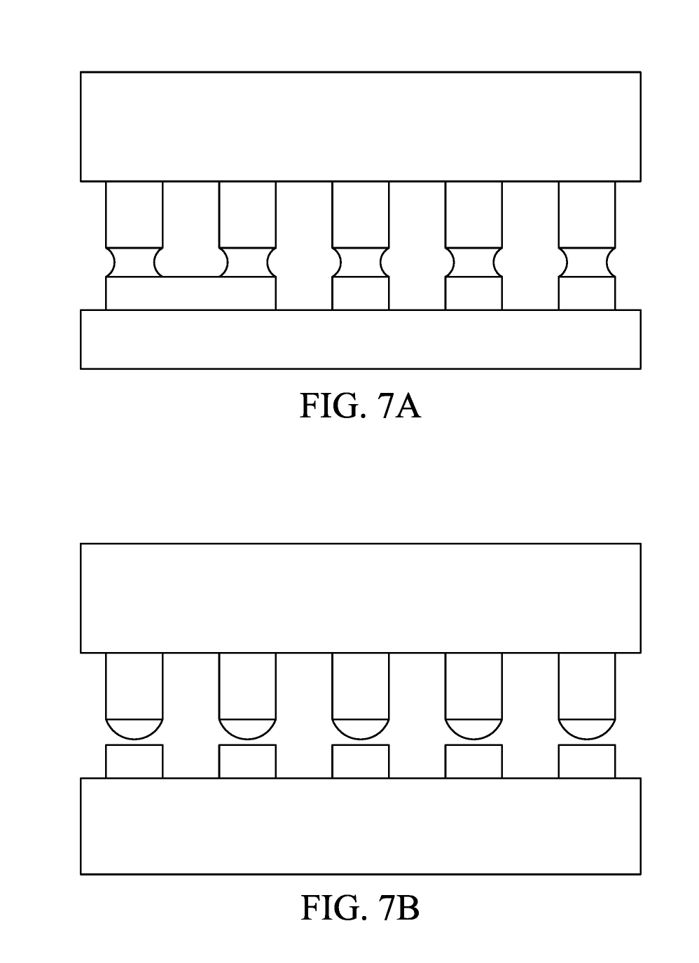

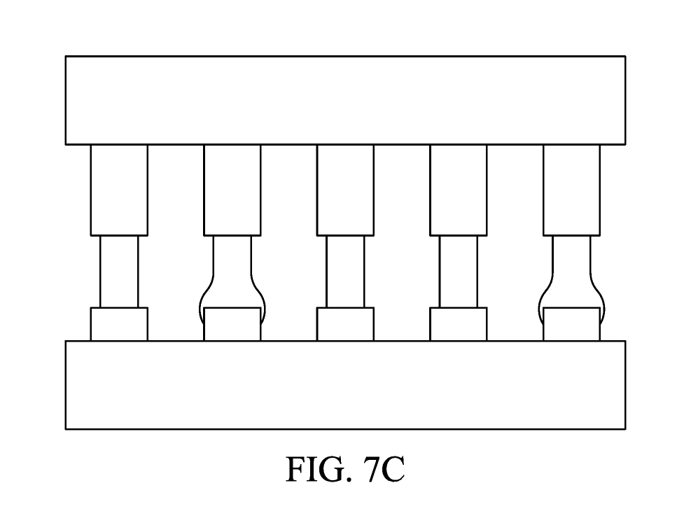

FIG. 7A is a schematic view illustrating a necking phenomenon of a comparative flip chip process, FIG. 7B is a schematic view illustrating a non-contact phenomenon of the comparative flip chip process, and FIG. 7C is a schematic view illustrating an overflow phenomenon of the comparative flip chip process. Each of solder bumps of a comparative flip chip structure includes a pillar, a coated layer fittingly formed on the pillar, and a solder ball formed on the coated layer. The pillar of each of the solder bumps includes a flat top surface. With such configurations, a comparative flip chip process may have the necking, non-contact or overflow phenomenon. As a result, the effectiveness of the comparative flip chip process is reduced.

Table 1 compares two sets of data, each corresponding to a height difference between a first solder bump and a second solder bump of another comparative flip chip structure. Referring to Set 1 of the data in Table 1, the height difference between the first solder bump and the second solder bump is 4.7 micrometers. Referring to Set 2 of the data in Table 1, a diameter of the first solder bump is increased and a diameter of the second solder bump is decreased, and the height difference between the first solder bump and the second solder bump is reduced to 3 micrometers. However, even if the height difference between the first solder bump and the second solder bump of another comparative flip chip structure is reduced, the height difference is still large enough to reduce the effectiveness of another comparative flip chip process.

TABLE 1

| | First Solder | Second Solder | Height |
|---|---|---|---|
| | Bump Diameter | Bump Diameter | Difference |
| | (μm) | (μm) | (μm) |
| Set 1 | 32.5 | 40 | 4.7 |
| Set 2 | 38.5 | 35 | 3 |

In conclusion, with the innovative structure of the flip chip structure 1 in accordance with some embodiments of the present disclosure, the height difference between the first solder bump 5 and the second solder bump 6 is greatly reduced. In addition, the adhesions of the first solder ball 53 and the second solder ball 63 are greatly increased. As a result, the necking, non-contact and overflow phenomenon are alleviated and a greater effectiveness of the flip chip process results. Consequently, the objective of the disclosure is achieved.

One aspect of the present disclosure provides a solder bump that has an innovative structure. The solder bump comprises a pillar, a coated layer fittingly formed on the pillar, and a solder ball formed on the coated layer. In some embodiments, the pillar includes a depression formed in the shape of an inverted cone and formed in a top surface of the pillar.

One aspect of the present disclosure provides a flip chip structure that can improve the effectiveness of the flip chip operation. The flip chip structure comprises a substrate; a bond pad formed on the substrate, a passivation layer formed on the substrate and surrounding the bond pad; a first solder bump formed on the bond pad and an adjacent portion of the passivation layer; and a second solder bump formed on a portion of the passivation layer and spaced apart from the first solder bump. In some embodiments, the first solder bump includes a first pillar formed on the bond pad and the adjacent portion of the passivation layer and extending in a vertical direction, a first coated layer fittingly formed on the first pillar, and a first solder ball formed on the first coated layer. In some embodiments, the second solder bump includes a second pillar formed on the portion of the passivation layer and extending in the vertical direction, a second coated layer fittingly formed on the second pillar, and a second solder ball formed on the second coated layer. In some embodiments, the first pillar includes a depression formed in the shape of an inverted cone and formed in a top surface of the first pillar.

One aspect of the present disclosure provides a method for forming a flip chip structure. The method includes the following steps. A substrate is provided. A bond pad is formed on the substrate. A passivation layer is formed on the substrate and surrounds the bond pad. A seed layer is sputtered on the bond pad and the passivation layer. A first solder bump and a second solder bump are simultaneously and respectively formed on a part of the seed layer that corresponds in position to the bond pad and an adjacent portion of the passivation layer and on another part of the seed layer that corresponds in position to a portion of the passivation layer. In some embodiments, the second solder bump is spaced apart from the first solder bump. In some embodiments, the first solder bump includes a first pillar formed on the part of the seed layer and extending in a vertical direction, a first coated layer fittingly formed on the first pillar, and a first solder ball formed on the first coated layer. In some embodiments, the second solder bump includes a second pillar formed on another part of the seed layer and extending in the vertical direction, a second coated layer fittingly formed on the first pillar, and a second solder ball formed on the second coated layer. In some embodiments, the first pillar includes a depression formed in the shape of an inverted cone and formed in a top surface of the first pillar.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A solder bump, comprising:
a pillar;
a coated layer fittingly formed on the pillar; and
a solder ball formed on the coated layer;
wherein the pillar includes a depression formed in a shape of an inverted cone and formed on a top surface of the pillar, a top surface of the coated layer is rougher than a bottom surface of the coated layer.

2. The solder bump as claimed in claim 1, wherein:
the solder ball includes a bottom portion formed in the shape of an inverted cone; and
a ratio of a height of the solder ball to a diameter of the pillar is between 0.6 and 0.8.

3. The solder bump as claimed in claim 2, wherein:
the coated layer is formed in the shape of an inverted cone.

4. A flip chip structure, comprising:
a substrate;
a bond pad formed on the substrate;
a passivation layer formed on the substrate and surrounding the bond pad;
a first solder bump formed on the bond pad and an adjacent portion of the passivation layer; and
a second solder bump formed on a portion of the passivation layer and spaced apart from the first solder bump;
wherein the first solder bump includes a first pillar formed on the bond pad and the adjacent portion of the passivation layer and extending in a vertical direction, a first coated layer fittingly formed on the first pillar, and a first solder ball formed on the first coated layer;
wherein the second solder bump includes a second pillar formed on the portion of the passivation layer and extending in the vertical direction, a second coated layer fittingly formed on the second pillar, and a second solder ball formed on the second coated layer;
wherein the first pillar includes a depression formed in a shape of an inverted cone and formed on a top surface of the first pillar; and
a top surface of the first coated layer is rougher than a bottom surface of the first coated layer.

5. The flip chip structure as claimed in claim 4, wherein a diameter of the first pillar of the first solder bump is different from a diameter of the second pillar of the second solder bump.

6. The flip chip structure as claimed in claim 5, wherein:
the first solder ball includes a bottom portion formed in the shape of an inverted cone; and
a ratio of a height of the first solder ball to the diameter of the first pillar is between 0.6 and 0.8.

7. The flip chip structure as claimed in claim 6, wherein:
the first coated layer is formed in the shape of an inverted cone.

8. The flip chip structure as claimed in claim 7, wherein the first pillar of the first solder bump is made of copper.

9. The flip chip structure as claimed in claim 8, wherein the first coated layer of the first solder bump is made of nickel.

10. The flip chip structure as claimed in claim 9, wherein the first solder ball of the first solder bump is made of tin-silver.

11. A method for preparing a flip chip structure, comprising:
providing a substrate;
forming a bond pad on the substrate;
forming a passivation layer on the substrate, wherein the passivation layer surrounds the bond pad;
sputtering a seed layer on the bond pad and the passivation layer; and
simultaneously forming a first solder bump on a part of the seed layer that corresponds in position to the bond pad and an adjacent portion of the passivation layer, and a second solder bump on another part of the seed layer that corresponds in position to a portion of the passivation layer;
wherein the second solder bump is spaced apart from the first solder bump;
wherein the first solder bump includes a first pillar formed on the part of the seed layer and extending in a vertical direction, a first coated layer fittingly formed on the first pillar, and a first solder ball formed on the first coated layer;
wherein the second solder bump includes a second pillar formed on another part of the seed layer and extending in the vertical direction, a second coated layer fittingly formed on the first pillar, and a second solder ball formed on the second coated layer; and
wherein the first pillar includes a depression formed in the shape of an inverted cone and formed in a top surface of the first pillar.

12. The method as claimed in claim 11, wherein the step of simultaneously forming the first and second solder bumps comprises:
coating a photoresist layer on the seed layer;
applying a lithography treatment to the photoresist layer;
simultaneously electroplating the first pillar on the part of the seed layer and the second pillar on another part of the seed layer;
respectively and simultaneously electroplating the first and second coated layers on the first and second pillars;
respectively and simultaneously applying surface treatments to the first and second coated layers;
respectively and simultaneously electroplating the first and second solder balls on the first and second coated layers;
stripping the photoresist layer from the seed layer;
applying a UBM etching treatment for stripping the remaining part of the seed layer; and
reflowing the first and second solder balls.

13. The method as claimed in claim 12, wherein a diameter of the first pillar is different from a diameter of the second pillar.

14. The method as claimed in claim 13, wherein:
the first solder ball includes a bottom portion formed in the shape of an inverted cone; and
a ratio of a height of the first solder ball to the diameter of the first pillar is between 0.6 and 0.8.

15. The method as claimed in claim 14, wherein:
the first coated layer is formed in the shaped of an inverted cone; and
a top surface of the first coated layer is rougher than a bottom surface of the first coated layer.

16. The method as claimed in claim 15, wherein the first pillar of the first solder bump is made of copper.

17. The method as claimed in claim 16, wherein the first coated layer of the first solder bump is made of nickel.

18. The method as claimed in claim 17, wherein the first solder ball of the first solder bump is made of tin-silver.

19. The method as claimed in claim 18, wherein:
the second solder ball includes a bottom portion formed in the shape of an inverted cone; and
a ratio of a height of the second solder ball to the diameter of the second pillar is between 0.6 and 0.8.

20. The method as claim in claim 19, wherein:
the second coated layer is formed in the shaped of an inverted cone; and
a top surface of the second coated layer is rougher than a bottom surface of the second coated layer.
